(19) United States
(12) Patent Application Publication
(10) Pub. No.: US 2012/0138905 A1
(43) Pub. Date: Jun. 7, 2012

(54) FLEXIBLE ORGANIC MEMORY DEVICE AND METHOD OF FABRICATING THE SAME

(75) Inventors: Jang-Sik LEE, Seoul (KR); Soo-Jin Kim, Seoul (KR)

(73) Assignee: Kookmin University Industry Academy Cooperation Foundation, Seoul (KR)

(21) Appl. No.: 13/163,957

(22) Filed: Jun. 20, 2011

(30) Foreign Application Priority Data
Dec. 1, 2010 (KR) 10-2010-0121350
Apr. 26, 2011 (KR) 10-2011-0038769

(51) Int. Cl. H01L 51/10; B82Y 10/00; B82Y 40/00; H01L 51/40

(52) U.S. Cl. 257/40; 438/99; 257/E51.007; 257/E51.001; 977/936; 977/840

(57) ABSTRACT

Provided are a flexible organic memory device and a method of manufacturing the same. The flexible organic memory device comprises a flexible substrate. A control gate electrode is disposed on the flexible substrate. A blocking organic insulating layer is disposed on the control gate electrode. A charge trapping layer is disposed on the blocking organic insulating layer, and includes a plurality of nanoparticles. A tunneling organic insulating layer is disposed on the charge trapping layer. An organic semiconductor layer is disposed on the tunneling organic insulating layer.

### CROSS-REFERENCE TO RELATED PATENT APPLICATION

This application claims the benefit of Korean Patent Application Nos. 10-2010-0121350, filed on Dec. 1, 2010 and 10-2011-0038769, filed on Apr. 26, 2011, in the Korean Intellectual Property Office, the disclosure of which is incorporated herein in its entirety by reference.

### BACKGROUND OF THE INVENTION

1. Field of the Invention

The present invention relates to a semiconductor device, and in particular, to a flexible organic memory device and a method of fabricating the same.

[Supported Product] The present invention includes results of studies supported by the National Research Foundation (NRF) grant funded by the Korea Government (MEST) (Grant Nos. 2008-0059952, 2009-0077593, 2010-0014925, and 2010-0015014), the “systemIC2010” project of Korea Ministry of Knowledge Economy (Grant No. 10030559) and the G.R.O.W. project of World Gold Council (Grant No. RP05-08).

2. Description of the Related Art

Requirements for high capacity in combination of small size in electronic products lead to a demand for high integration memory devices used in such electronic devices. However, due to the limitation on a semiconductor integration process, high integration of such memory devices is limited. A nanoparticle-based memory device has been considered as an alternative to such memory devices since it has a simple structure and is appropriate for a multi level cell (MLC) operation. Meanwhile, recently, research on flexible apparatuses including flexible displays and the like is being carried out, and memory devices used in such flexible apparatuses are also required to have a flexible characteristic.

### SUMMARY OF THE INVENTION

However, typically, a flexible device is fabricated by using a complicated method, including forming a device on a glass substrate and then transferring the device on a flexible substrate. An aspect of the present invention provides an economic flexible organic memory device and a method of fabricating the same, using a flexible substrate. The aspect is exemplary, and the present invention is not limited thereto.

According to an aspect of the present invention, there is provided a flexible organic memory device. A flexible substrate may be provided, and a control gate electrode may be disposed on the flexible substrate. A blocking organic insulating layer may be disposed on the control gate electrode. A charge trapping layer may be disposed on the blocking organic insulating layer and may include a plurality of nanoparticles. A tunneling organic insulating layer may be disposed on the charge trapping layer. An organic semiconductor layer may be disposed on the tunneling organic insulating layer. A source electrode and a drain electrode may be spaced apart from each other on the organic semiconductor layer.

In the flexible organic memory device, the charge trapping layer may further include an organic adhesive layer for fixing a plurality of nanoparticles on the blocking organic insulating layer.

In the flexible organic memory device, the organic adhesive layer may further include a capping organic insulating layer on the nanoparticles.

In the flexible organic memory device, each of the control gate electrode, the source electrode, and the drain electrode may include a transparent conductor. Furthermore, the flexible organic memory device may further include buffer layers between the source electrode and the organic semiconductor layer and between the drain electrode and the organic semiconductor layer.

In the flexible organic memory device, the flexible organic memory device may overall be transparent in a visible light region.

According to another aspect of the present invention, a method of fabricating a flexible organic memory device is provided. A control gate electrode may be formed on a flexible substrate. A blocking organic insulating layer may be formed on the control gate electrode. A charge trapping layer including a plurality of nanoparticles may be formed on the blocking organic insulating layer. A tunneling organic insulating layer may be formed on the charge trapping layer. An organic semiconductor layer may be formed on the tunneling organic insulating layer. A source electrode and a drain electrode may be formed on the organic semiconductor layer on both sides of the control gate electrode.

In the method, the forming of the charge trapping layer may include: forming an organic adhesive layer on the blocking organic insulating layer; and forming a plurality of nanoparticles on the organic adhesive layer. Furthermore, the forming of the charge trapping layer may further include forming a capping organic insulating layer on the nanoparticles.

In the method, each of the control gate electrode, the source electrode, and the drain electrode may include a transparent conductor, and buffer layers may be formed between the source electrode and the organic semiconductor layer and between the drain electrode and the organic semiconductor layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic perspective view of a flexible organic memory device according to an embodiment of the present invention in which portions of the flexible organic memory device are cut;

FIG. 2 is a cross-sectional view taken along a line II-II of the flexible organic memory device of FIG. 1;

FIG. 3 is a cross-sectional view of a flexible organic memory device according to another embodiment of the present invention;

FIG. 4 is a schematic view to explain a bending test process of a flexible organic memory device according to embodiments of the present invention;

FIGS. 5 to 7 are cross-sectional views to explain a method of fabricating a flexible organic memory device, according to an embodiment of the present invention;

FIG. 8 shows a graph showing program/erase characteristics of flexible organic memory devices according to embodiments of the present invention;

FIG. 9 shows a graph showing endurance characteristics of flexible organic memory devices according to embodiments of the present invention;

FIG. 10 shows a graph showing retention characteristics of flexible organic memory devices according to embodiments of the present invention;

FIG. 11 shows a graph showing bending test results of flexible organic memory devices according to embodiments of the present invention;

FIG. 12 is a cross-sectional view of a flexible organic memory device according to another embodiment of the present invention;

FIG. 13 is a cross-sectional view of a flexible organic memory device according to another embodiment of the present invention;

FIG. 14 is a schematic view to explain a bending test process of the flexible organic memory device of FIG. 12; and

FIG. 15 shows a graph showing a program/erase characteristic of the flexible organic memory device of FIG. 12.

### DETAILED DESCRIPTION OF THE INVENTION

Reference will now be made in detail to embodiments, examples of which are illustrated in the accompanying drawings. In this regard, the present embodiments may have different forms and should not be construed as being limited to the descriptions set forth herein. Accordingly, the embodiments are merely described below, by referring to the figures, to explain aspects of the present invention. In the drawings, sizes of elements may be enlarged or shrunk for ease of description.

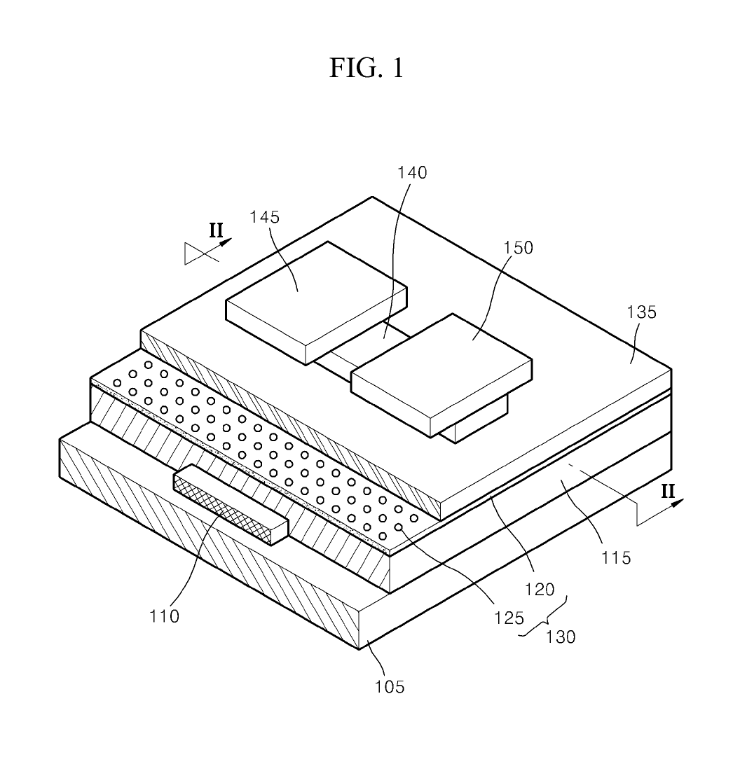

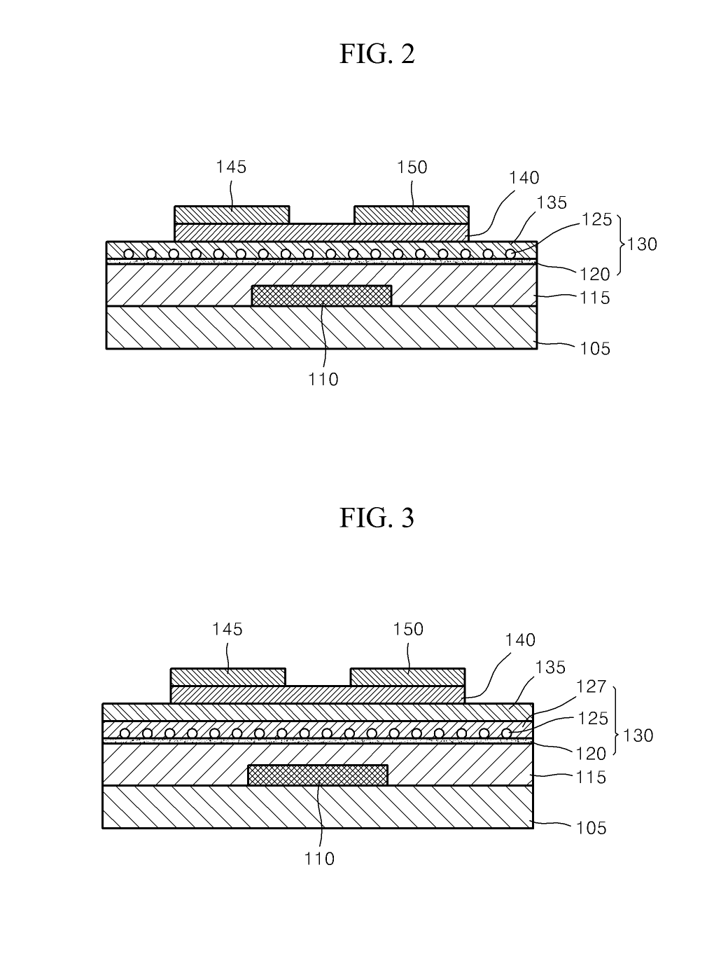

FIG. 1 is a schematic perspective view of a flexible organic memory device according to an embodiment of the present invention, in which portions of the flexible organic memory device are cut, and FIG. 2 is a cross-sectional view taken along a line II-II of the flexible organic memory device of FIG. 1.

Referring to FIGS. 1 and 2, a flexible substrate 105 may be provided. For example, the flexible substrate 105 may include a plastic substrate having flexibility. For example, the plastic substrate may include a polymer resin such as poly carbonate (PC), poly arylate (PAR), poly ether sulfone (PES), or polyimide (PI). The plastic substrate is required to have flexibility, and when used in a display device or the like, is further required to have transparency.

A control gate electrode 110 may be disposed on the flexible substrate 105. The control gate electrode 110 may control on and off operations of a memory cell. The control gate electrode 110 may include various conductive materials. For example, the control gate electrode 110 may include metal, metal silicide, metal nitride, polysilicon, etc. As another example, for entire transparency purpose, the control gate electrode 110 may include an organic conductive material, for example, a conductive polymer.

The blocking organic insulating layer 115 may be disposed on the control gate electrode 110. The blocking organic insulating layer 115 may prevent loss of charges of a charge trapping layer 130 due to reverse tunneling of the charges into the control gate electrode 110. For example, the blocking organic insulating layer 115 may include proper organic insulating materials, for example, at least one selected from the group consisting of polymethyl methacrylate (PMMA), polyvinyl phenol (PVP), and polyvinyl alcohol (PVA).

The charge trapping layer 130 may be disposed on the blocking organic insulating layer 115. The charge trapping layer 130 may have a plurality of nanoparticles 125 having a charge storage capability. For example, the charge trapping layer 130 may include an organic adhesive layer 120 disposed on the blocking organic insulating layer 115 and a plurality of nanoparticles 125 fixed on the organic adhesive layer 120.

For example, the organic adhesive layer 120 may include 3-aminopropyltriethoxysilane (APTES). As another example, the organic adhesive layer 120 may be formed as a polymer electrolytic membrane, for example, a poly allylamine hydrochloride (PAH) layer. The polymer electrolytic membrane may include poly allylamine hydrochloride (PAH) layers facing each other and ploy styrenesulfonate (PSS) layers interposed between the PAH layers.

The nanoparticles 125 may have a charge trapping capability, and the charge trapping may be associated with data program. According to the crystal type, size, function, etc of the nanoparticles, the nanoparticles 125 may be referred to as nano dots, quantum dots, nanocrystals, etc. For example, the nanoparticles 125 may include various metallic materials, for example, at least one selected from the group consisting of cobalt (Co), iron (Fe), nickel (Ni), chromium (Cr), gold (Au), silver (Ag), copper (Cu), aluminum (Al), platinum (Pt), tin (Sn), tungsten (W), ruthenium (Ru), palladium (Pd), and cadmium (Cd). According to another embodiment, the nanoparticles 125 may include semiconductor materials, for example, silicon, germanium, silicon-germanium, etc.

A tunneling organic insulating layer 135 may be disposed on the charge trapping layer 130. The tunneling organic insulating layer 135 may be used as a charge tunneling passage between the organic semiconductor layer 140 and the charge trapping layer 130. For example, the tunneling organic insulating layer 135 may include proper organic insulating materials, for example, at least one selected from the group consisting of polymethyl methacrylate (PMMA), polyvinyl phenol (PVP), and polyvinyl alcohol (PVA).

An organic semiconductor layer 140 may be disposed on the tunneling organic insulating layer 135. The organic semiconductor layer 140 may provide charges with a passage via an inversion layer when a memory cell operates. In the present embodiment, the organic semiconductor layer 140 may include organic materials instead of typical silicon wafer so as to have flexibility.

For example, the organic semiconductor layer 140 may include an organic material selected from the group consisting of pentacene, tetracene, anthracene, naphthalene, alpha-6-thiophene, alpha-4-thiophene, a perylene and derivative thereof, a ubrene and derivative thereof, a coronene and derivative thereof, a perylene tetracarboxylic diimide and derivative thereof, a perylene tetracarboxylic dianhydride and derivative thereof, a polythiophene and derivative thereof, a polyparaphenylenevinylene and derivative thereof, a polyparaphenylene and derivative thereof, a polyflorene and derivative thereof, a polythiophenevinylene and derivative thereof, a polythiophene-heterocyclic aromatic copolymer and derivative thereof, a oligoacene of naphthalene and derivative thereof, a oligothiophene of alpha-5-thiophene and derivative thereof, a metal-containing or metal-free phthalocyanine and derivative thereof, a pyromellitic dianhydride and derivative thereof, a pyromellitic diimide and derivative thereof, a perylenetetracarboxylic acid dianhydride and derivative thereof, a perylenetetracarboxylic dimide and derivative thereof, etc.

A source electrode 145 may be disposed being connected to the organic semiconductor layer 140 on a side of the control gate electrode 110, and a drain electrode 150 may be disposed being connected to the organic semiconductor layer 140 on another side of the control gate electrode 110. For example, the source electrode 145 and the drain electrode 150 may be spaced apart from each other on the organic semiconductor layer 140, with the control gate electrode 110 interposed therebetween. The arrangement of the source electrode 145 and the drain electrode 150 may vary.

The source electrode 145 and the drain electrode 150 may each include various conductive materials. For example, each of the source electrode 145 and the drain electrode 150 may include metal, metal silicide, metal nitride, polysilicon, etc. As another example, for entire transparency purpose, each of the source electrode 145 and the drain electrode 150 may include an organic conductive material, for example, a conductive polymer.

FIG. 3 is a cross-sectional view of a flexible organic memory device according to another embodiment of the present invention. The flexible organic memory device according to the present embodiment is fabricating by changing a portion of the flexible organic memory device of FIGS. 1 and 2, and accordingly, redundant descriptions that are presented with regard to the flexible organic memory devices according to the present and previous embodiments will not be provided herein.

Referring to FIG. 3, the charge trapping layer 130 may further include a capping organic insulating layer 127 on the nanoparticles 125. For example, the capping organic insulating layer 127 may further include a proper organic dielectric material. For example, the charge trapping layer 130 may include a material that is used to form the organic adhesive layer 120 or the tunneling insulating layer 135.

The flexible organic memory devices as described above may have 3 (three) terminals including the control gate electrode 110, the source electrode 145, and the drain electrode 150, and may have a reverse structure in which the organic semiconductor layer 140 is disposed on the control gate electrode 110. The devices may be used as a nanoparticle-based non-volatile memory device by using the charge trapping layer 130. In particular, a multi-level cell (MLC) operation may be stably embodied by injecting charges to the nanoparticles 125 in phases.

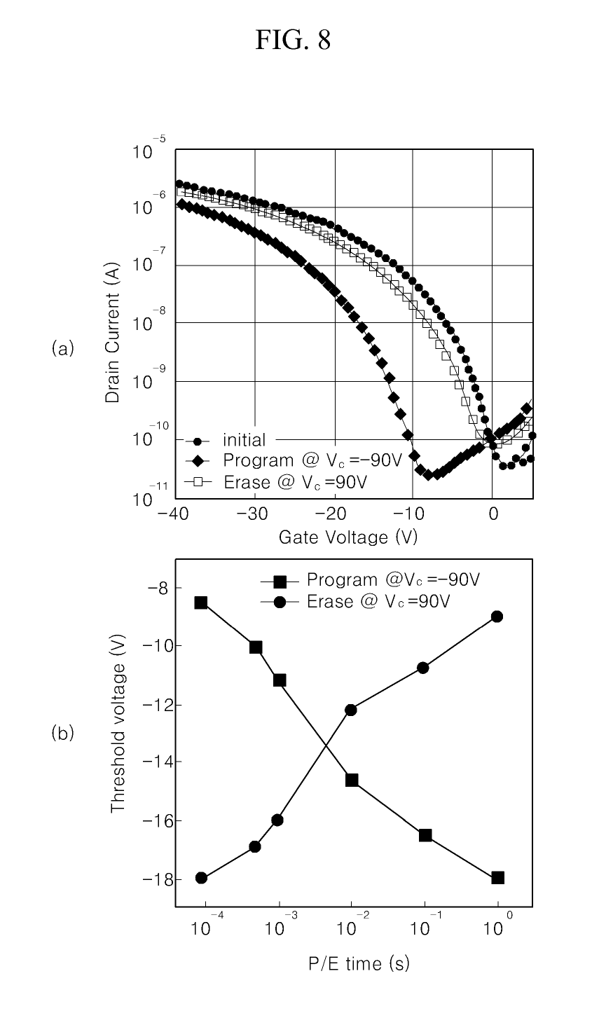

FIG. 8 shows a graph showing program/erase characteristics of flexible organic memory devices according to embodiments of the present invention. FIG. 8A shows a graph of a drain current with respect to a gate voltage, and FIG. 8B shows a graph of a threshold voltage with respect to a program/erase (P/E) time.

Referring to FIG. 8, when a P/E voltage is applied to a control gate electrode (see 115 of FIG. 1), a threshold voltage and a drain current begin to change. The change in threshold voltage and transition of drain current after program indicate that charges, for example, holes are trapped in nanoparticles (125 of FIG. 1). In FIG. 8A, memory window is about 10 V.

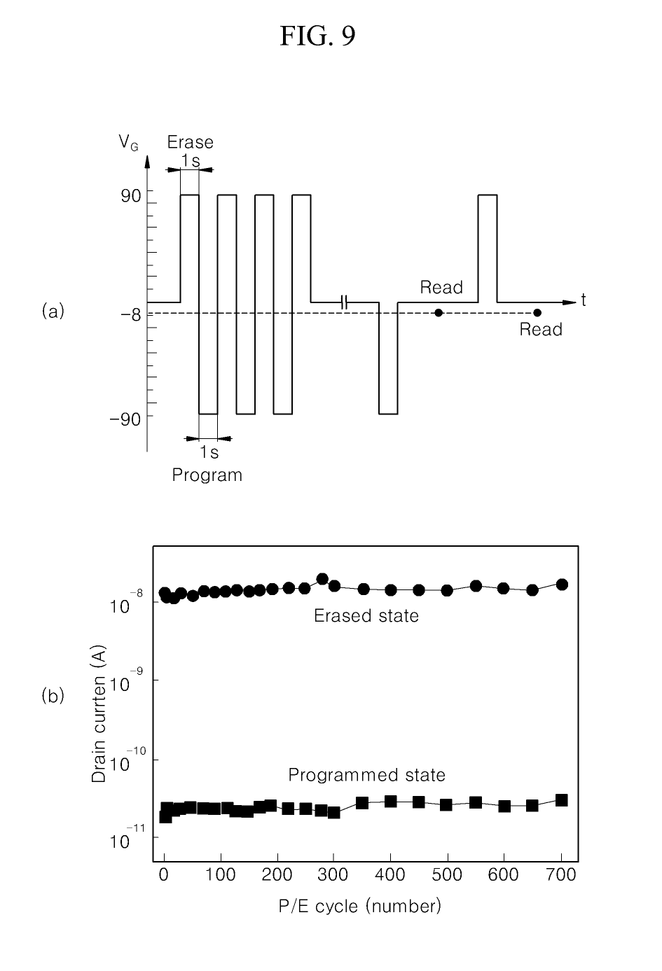

FIG. 9 shows a graph showing endurance characteristics of flexible organic memory devices according to embodiments of the present invention. FIG. 9A illustrates a pulse sequence for an endurance test that reads a programmed state and an erased state after a P/E operation is repeatedly performed during a predetermine cycle. FIG. 9B shows a graph of drain current with respect to a P/E cycle in cases of a programmed state and an erased state.

Referring to FIG. 9, the drain current in the programmed state and the erased state is almost constantly maintained even after about 700 P/E cycles. From this result, it is expected that flexible organic memory devices according to embodiments of the present invention may retain their reliability when repeatedly used, and furthermore, may have a commercially available level of endurance characteristics.

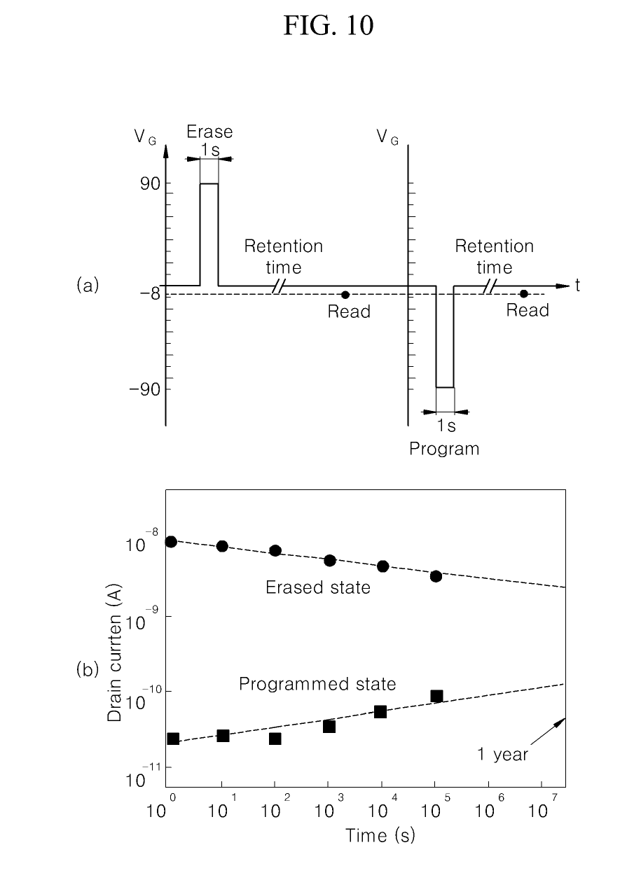

FIG. 10 shows a graph showing retention characteristics of flexible organic memory devices according to embodiments of the present invention. FIG. 10A illustrates a pulse sequence for a retention test that reads a programmed state and an erased state after a predetermined period of time, is retained after erase and program operations. FIG. 10B shows a graph of drain current with respect to retention time in cases of a programmed state and an erased state.

Referring to FIG. 10, as the retention time is increased, the drain currents in the programmed state and the erased state are slowly changed. However, even after 1 year, the programmed state and the erased state are still distinguished from each other. In addition, this level of change is still lower than those of typical other organic semiconductor devices. Accordingly, it is assumed that flexible organic memory devices according to embodiments of the present invention have excellent data retention characteristics.

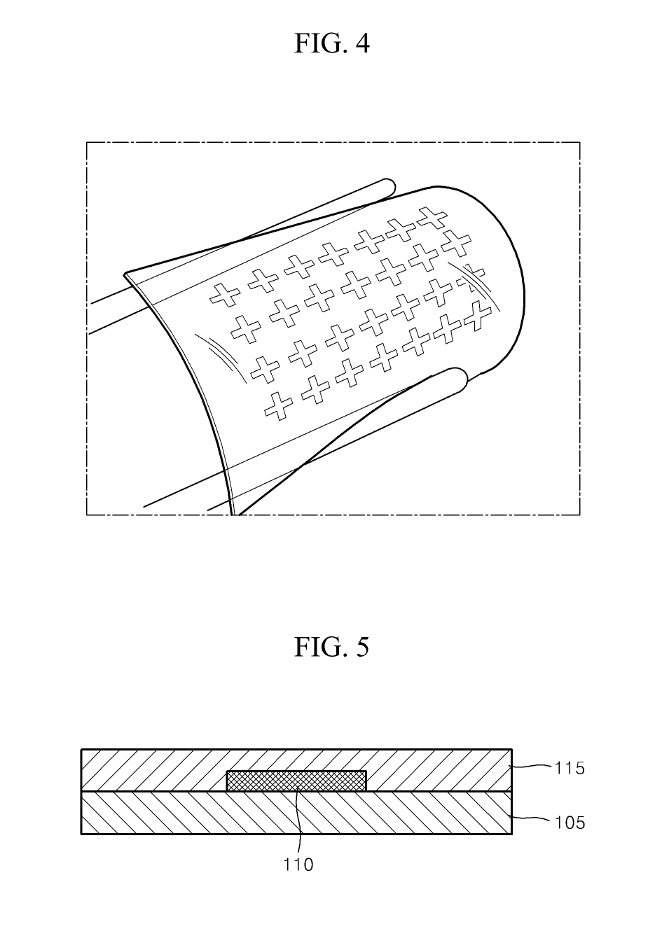

Also, flexible organic memory devices according to embodiments of the present invention are mostly or overall formed of organic materials, and thus, as illustrated in FIG. 4, the flexible organic memory devices are overall flexible. Furthermore, since the flexible organic memory devices are formed of transparent organic materials and thus, the flexible organic memory devices are overall or mostly transparent, the flexible organic memory devices are appropriate for display devices, etc. In FIG. 4, a control gate electrode, a source electrode, a drain electrode are formed of metal for visibility purpose.

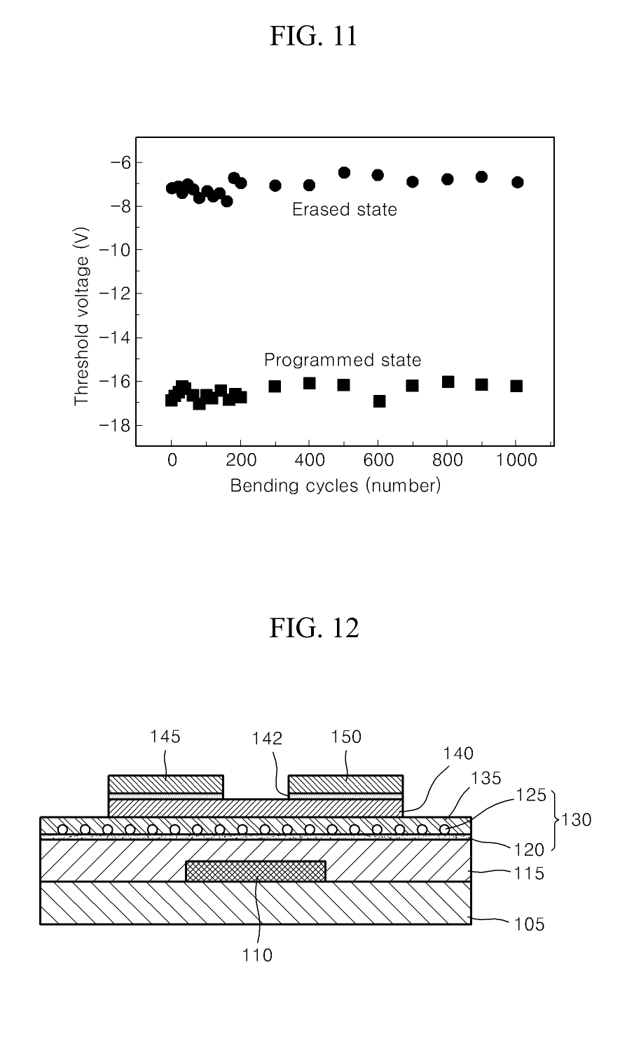

FIG. 11 shows a graph showing bending test results of flexible organic memory devices according to embodiments of the present invention. A bending test was performed by repeatedly bending samples in such a way that the radius of curvature is about 20 mm.

Referring to FIG. 11, even after about 1,000 times of bending, threshold voltages in the programmed state and the erased state are almost constantly maintained. Accordingly, it is expected that flexible organic memory devices according to embodiments of the present invention have excellent flexibility, and accordingly, application thereof in various flexible apparatuses is possible.

FIGS. 5 to 7 are cross-sectional views to explain a method of fabricating a flexible organic memory device, according to an embodiment of the present invention.

Referring to FIG. 5, the control gate electrode 110 is formed on the flexible substrate 105. For example, the control gate electrode 110 may be formed by forming a proper conductive layer and then patterning the conductive layer by photolithography or etching.

Subsequently, the blocking organic insulating layer 115 may be formed on the control gate electrode 110. For example, the blocking organic insulating layer 115 may be formed by coating a proper organic material on the control gate electrode 110 by solution-process or spin coating. For example, the blocking organic insulating layer 115 may include at least one selected from the group consisting of polymethyl methacrylate (PMMA), polyvinyl phenol (PVP), and polyvinyl alcohol (PVA).

Optionally, the blocking organic insulating layer 115 may include a cross-linked polyvinylphenol (PVP) that is cross-linked at a low temperature of room temperature to 200° C. or less, in particular, 180° C. or less. These temperature ranges may be the highest temperature range among flexible organic memory devices according to the present embodiment, but still lower than typical 300° C. As described above, heat that is applied to the flexible substrate 105 may be lowered by decreasing the crosskicking temperature, and accordingly, an organic memory device is fabricated directly on the flexible substrate 105 without use of a glass substrate.

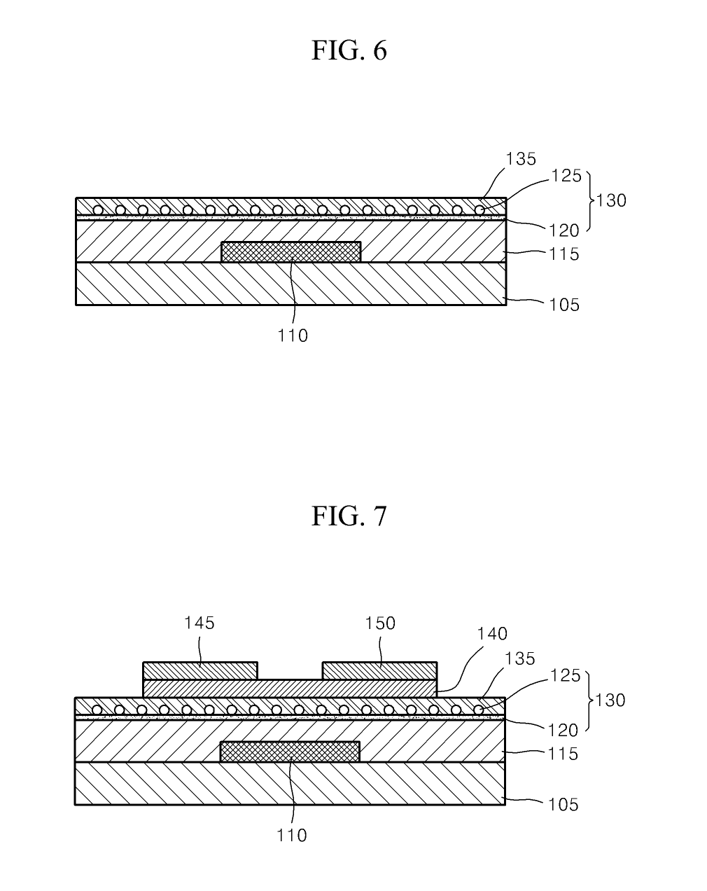

Referring to FIG. 6, the organic adhesive layer 120 may be formed on the blocking organic insulating layer 115. Subsequently, the nanoparticles 125 are fixed on the organic adhesive layer 120, thereby completing formation of the charge trapping layer 130. For example, the nanoparticles 125 may be formed by citrate reduction.

For example, 250 Ml of 2 mM HAuCl₄ is heated at a temperature of about 70° C. while stirring, and then, 25 Ml of 68 mM sodium citrate solution is added thereto, turning the resultant solution from yellow to violet, thereby forming the nanoparticles 125. An average diameter of gold nanoparticles formed as described above may be about 15±3.9 nm.

Alternatively, a micellar solution prepared by adding a nanoparticle procurer into a block copolymer solvent may be used to form the nanoparticles 125. For example, the block copolymer solvent may be prepared by dissolving polystyrene-block-poly 4-vinyl pyridine (PS-b-P4VP) in toluene, and the nanoparticle procurer may be HAuCl₄ solution. If the HAuCl₄ solution is added to the block copolymer solvent, Au may enter a P4VP core structure by substitution, thereby having a nanoparticle form. Subsequently, the polymer micellar layer is treated with plasma to synthesize the nanoparticles 125. For example, if the polymer micellar layer including Au nanoparticles is treated with oxygen plasma, the PS corona structure is removed, thereby forming Au oxide nanoparticles and subsequently, the unstable Au oxide nanoparticles may be reduced into the nanoparticles 125 even at room temperature.

Then, the tunneling organic insulating layer 135 may be formed on the charge trapping layer 130. The tunneling organic insulating layer 135 and the blocking organic insulating layer 115 may be formed identical or different materials. The forming of the tunneling organic insulating layer 135 may be understood by substantially referring to the forming of the blocking organic insulating layer 115.

Optionally, before the tunneling organic insulating layer 135 is formed, as illustrated in FIG. 3, the capping organic insulating layer 127 may be formed on the nanoparticles 125. The forming of the capping organic insulating layer 127 may be referred to the forming of the blocking organic insulating layer 115 as described above.

Referring to FIG. 7, the organic semiconductor layer 140 may be formed on the tunneling organic insulating layer 135. For example, a pentacene layer is formed by vacuum deposition at a temperature of about 60° C. to form the organic semiconductor layer 140.

Subsequently, the source electrode 145 and the drain electrode 150 may be formed. For example, the source electrode 145 and the drain electrode 150 may be formed by sputtering using a shadow mask. Alternatively, the source electrode 145 and the drain electrode 150 may be formed by depositing a conductive layer and then patterning the conductive layer.

According to the fabrication method as described above, all the process including from the forming of the control gate electrode 110 to the forming of the source electrode 145 and the drain electrode 150 may be performed at a low temperature of room temperature to 200° C. or less, in particular, 180° C. or less.

FIG. 12 is a cross-sectional view of a flexible organic memory device according to another embodiment of the present invention. The flexible organic memory device according to the present embodiment is fabricated by either changing a part of the flexible organic memory device of FIGS. 1 and 2 or adding some constituents thereto. Accordingly, redundant descriptions presented with regard to the flexible organic memory devices according to the embodiments will not be provided herein.

Referring to FIG. 12, each of the control gate electrode 110, the source electrode 145, and the drain electrode 150 may include a transparent conductor for overall transparency. For example, the transparent conductor may include indium tin oxide (ITO) or tin-doped indium oxide. ITO may be a solid solution of indium oxide and tin oxide.

The buffer layers 142 may be disposed between the source electrode 145 and the organic semiconductor layer 140, and between the drain electrode 150 and the organic semiconductor layer 140. If ITO that constitutes each of the source electrode 145 and the drain electrode 150 directly contacts the organic semiconductor layer 140, a contact resistance therebewteen is known to be very high. The buffer layers 142 may be selected so as to lower the contact resistance therebetween.

For example, to lower the contact resistance, the buffer layers 142 may include a transition metal oxide, for example, molybdenum trioxide (MoO₃). Also, the buffer layers 142 may be used as a hole injector for arranging energy levels between the organic semiconductor layer 140 and each of the source electrode 145 and the drain electrode 150.

The flexible organic memory device according to the present embodiment is mostly or overall formed of organic materials, and thus, as illustrated in FIG. 14, the flexible organic memory device may have overall transparency and flexibility. Due to the transparency and flexibility, the flexible organic memory device may be used as a display device.

According to experiments of the inventors of the present invention, a poly ether sulfone (PES) substrate has a transmittance of about 85% in a visible light region, that is, in a wavelength range from about 400 nm to 700 nm, and an organic TFT device including a PES substrate, pentacene, PVP, ITO, etc. also has a transmittance of about 85% in the visible light region. Meanwhile, an organic memory device using a PES substrate, PVP, Au nanoparticles, pentacene, MoO₃, ITO, etc. has a transmittance of about 61% to 69% in the visible light region. That is, although transmittance of the organic memory device is lower than that of the organic TFT device, the organic memory device has overall transmittance of 60% or more. That is, the organic memory device has overall transparency. Meanwhile, the transmittance of the organic memory device is expected to be 70% or more by changing a portion of the fabrication method or using other metal nanoparticles instead of the Au nanoparticles.

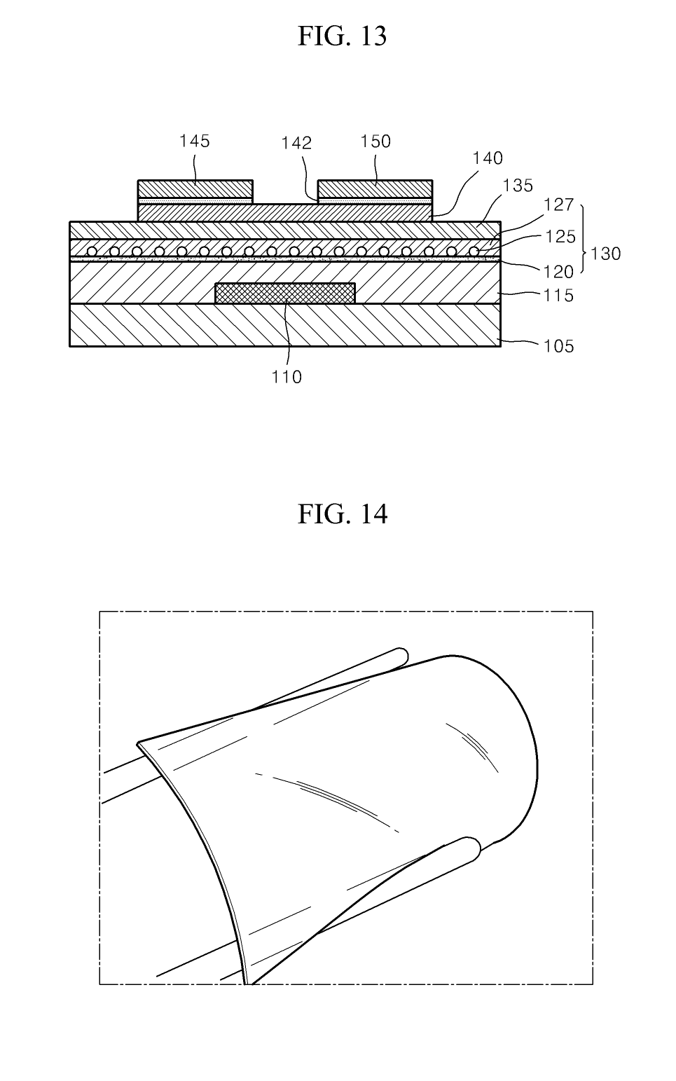

FIG. 13 is a cross-sectional view of a flexible organic memory device according to another embodiment of the present invention. The flexible organic memory device according to the present embodiment is fabricating by changing a portion of the flexible organic memory device of FIG. 12, and thus, redundant descriptions that are presented with regard to the flexible organic memory devices according to the embodiments will not be provided herein.

Referring to FIG. 13, the charge trapping layer 130 may further include the capping organic insulating layer 127 on the nanoparticles 125. For example, the capping organic insulating layer 127 may include a proper organic dielectric material. For example, the charge trapping layer 130 may be formed of a material that is used to form the organic adhesive layer 120 or the tunneling insulating layer 135, each of which is adjacent to the capping organic insulating layer 127.

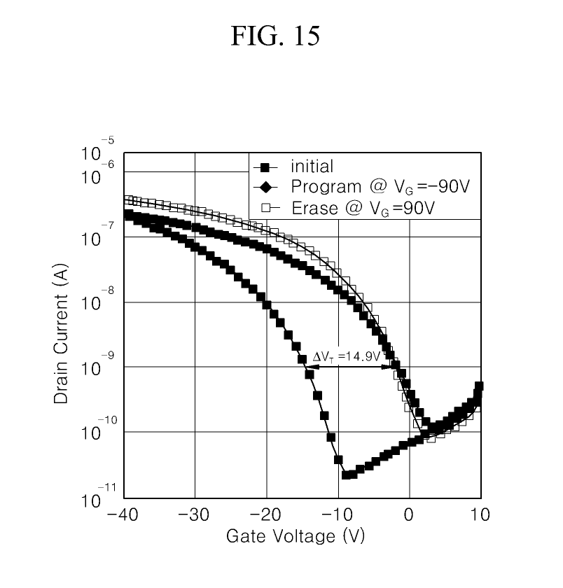

FIG. 15 shows a graph showing a program/erase characteristic of the flexible organic memory device of FIG. 12.

Referring to FIG. 15, when a P/E voltage is applied to a control gate electrode (see 115 of FIG. 12), a threshold voltage and a drain voltage begin to change. The change in threshold voltage and transition of drain current after program indicate that charges, for example, holes are trapped in nanoparticles (see 125 of FIG. 12). In FIG. 15, memory window is about 14.9 V.

The memory devices illustrated in FIGS. 12 and 13 may be manufactured by using a method that is partially modified from the method explained above with regard to FIGS. 5 to 7. For example, following the process explained with reference to FIG. 7, the buffer layer 142 may be formed on the organic semiconductor layer 140. For example, the buffer layer 142 may be a MoO₃ layer formed by thermal evaporation. The buffer layer 142 may be formed by either using a shadow mask, or formed by forming a layer and then patterning the layer.

Subsequently, the source electrode 145 and the drain electrode 150 may be formed on the buffer layer 142. The source electrode 145 and the drain electrode 150 may be formed by sputtering using a shadow mask. Alternatively, each of the source electrode 145 and the drain electrode 150 may be formed by depositing a conductive layer and then patterning the conductive layer.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A flexible organic memory device comprising:
a flexible substrate;
a control gate electrode on the flexible substrate;
a blocking organic insulating layer on the control gate electrode;
a charge trapping layer that is disposed on the blocking organic insulating layer and comprises a plurality of nanoparticles;
a tunneling organic insulating layer on the charge trapping layer;
an organic semiconductor layer on the tunneling organic insulating layer; and
a source electrode connected to the organic semiconductor layer on a side of the control gate electrode; and
a drain electrode connected to the organic semiconductor layer on another side of the control gate electrode.

2. The flexible organic memory device of claim 1, wherein the charge trapping layer further comprises an organic adhesive layer for fixing a plurality of nanoparticles on the blocking organic insulating layer.

3. The flexible organic memory device of claim 2, wherein the organic adhesive layer comprises 3-aminopropyltriethoxysilane (APTES).

4. The flexible organic memory device of claim 2, wherein the charge trapping layer further comprises a capping organic insulating layer on the nanoparticles.

5. The flexible organic memory device of claim 2, wherein each of the tunneling organic insulating layer and the blocking organic insulating layer comprises at least one selected from the group consisting of polymethyl methacrylate (PMMA), polyvinyl phenol (PVP), and polyvinyl alcohol (PVA).

6. The flexible organic memory device of claim 1, wherein each of the control gate electrode, the source electrode, and the drain electrode comprises a transparent conductor.

7. The flexible organic memory device of claim 6, further comprising buffer layers between the source electrode and the organic semiconductor layer and between the drain electrode and the organic semiconductor layer.

8. The flexible organic memory device of claim 7, wherein the buffer layers comprise a conductive transition metal oxide.

9. The flexible organic memory device of claim 8, wherein the conductive transition metal oxide comprises molybdenum trioxide (MoO₃).

10. The flexible organic memory device of claim 6, wherein the flexible organic memory device is overall transparent in a visible light region.

11. A method of fabricating a flexible organic memory device, the method comprising:
forming a control gate electrode on a flexible substrate;
forming a blocking organic insulating layer on the control gate electrode;
forming a charge trapping layer comprising a plurality of nanoparticles on the blocking organic insulating layer;
forming a tunneling organic insulating layer on the charge trapping layer;
forming an organic semiconductor layer on the tunneling organic insulating layer; and
forming a source electrode and a drain electrode on the organic semiconductor layer on both sides of the control gate electrode.

12. The method of claim 11, wherein the forming of the charge trapping layer comprises:
forming an organic adhesive layer on the blocking organic insulating layer; and
forming a plurality of nanoparticles on the organic adhesive layer.

13. The method of claim 12, wherein the forming of the charge trapping layer further comprises
forming a capping organic insulating layer on the nanoparticles.

14. The method of claim 11, wherein each of the blocking organic insulating layer and the tunneling organic insulating layer comprises polyvinylphenole (PVP) that is cross-linked at a temperature of room temperature to 200° C. or less.

15. The method of claim 14, wherein the forming of the control gate, the forming of the blocking organic insulating layer, the forming of the charge trapping layer, the forming of the tunneling organic insulating layer, and the forming of the organic semiconductor layer are performed at a temperature of room temperature to 180° C. or less.

16. The method of claim 11, wherein each of the control gate electrode, the source electrode, and the drain electrode comprises a transparent conductor, and the method further comprises
forming buffer layers between the source electrode and the organic semiconductor layer and between the drain electrode and the organic semiconductor layer.

17. The method of claim 16, wherein the buffer layers each comprises a conductive transition metal oxide.
